(19) United States
(12) Patent Application Publication
(10) Pub. No.: US 2012/0112311 A1
(43) Pub. Date: May 10, 2012

(54) Electrical Fuses Using Junction Breakdown and Semiconductor Integrated Circuits Including the Same

(75) Inventors: Yong Sang Cho, Hwaseong-si (KR); Dae Lim Kang, Hwaseong-si (KR); Sung Soo Kim, Bucheon-si (KR); Jong Ik Nam, Hwaseong-si (KR); Keun Bong Lee, Yongin-si (KR); Hye-Won Shim, Seoul (KR)

(73) Assignee: Samsung Electronics Co., Ltd.

(21) Appl. No.: 13/239,437

(22) Filed: Sep. 22, 2011

(30) Foreign Application Priority Data
Nov. 10, 2010 (KR) 10-2010-0111780

(51) Int. Cl. H01L 29/86

(52) U.S. Cl. 257/529; 257/E29.325

(57) ABSTRACT

An electrical fuse includes first and second active regions doped with respective first-type and second-type impurities that form a horizontal P/N junction, first and second spaced apart silicide layers on respective portions of the top surfaces of the first and second active regions, and first and second contacts on the respective top surfaces of the first and second silicide layers. When a first reverse voltage that is higher than a threshold voltage is applied to the electrical fuse through the first and second contacts, the P/N junction is broken down by a reverse current flowing between the first and second active regions so that the electrical fuse is rendered conductive in response to a second reverse voltage that is less than the threshold voltage.

### CROSS-REFERENCE TO RELATED APPLICATION

This application claims priority under 35 U.S.C. §119(a) from Korean Patent Application No. 10-2010-0111780 filed on Nov. 10, 2010, the disclosure of which is hereby incorporated by reference in its entirety.

### BACKGROUND

The present invention relates to semiconductor devices, and more particularly, to electrical fuses for semiconductor devices and semiconductor integrated circuits that include such fuses.

As the storage capacity and degree of integration of semiconductor devices is increased, so does the likelihood that defects will occur in semiconductor cells during the manufacture of such devices. These defects cause production yields to decrease. In general, when a semiconductor device has several defective cells or even a single defective cell, it may not, in some circumstances, be appropriate to ship the device as a product. Various approaches have been developed for improving the production yield of semiconductor devices that have these high degrees of integration. One such approach is the use of fuses to provide redundancy.

Various types of fuses have been employed to provide redundancy in semiconductor memory devices, including mechanical laser fuses and, more recently, electrical fuses.

An increase in the demand for electrical fuses was realized with the introduction of mobile products such as security keys and compact memory devices. In these applications, a fuse that can also be programmed later is preferred to a fixed code using a laser fuse.

Conventional electrical fuses are largely divided into polysilicide-based electrical fuses and oxide-based electrical fuses. Polysilicide-based electrical fuses operate based on a change in resistance that occurs when polysilicide on an active region is programmed using electromigration. Oxide-based electrical fuses operate based on a change in gate leakage current that occurs when a gate oxide is broken down.

### SUMMARY

Some embodiments of the present invention provide an electrical fuse having high compatibility and a semiconductor integrated circuit including the same.

Some embodiments of the present invention also provide an electrical fuse having a reliable structure and a semiconductor integrated circuit including the same.

According to some embodiments of the present invention, electrical fuses are provided that include a first active region doped with first-type impurities, a second active region doped with second-type impurities which forms a horizontal P/N junction with the first active region, a first silicide layer on a portion of a top surface of the first active region, a second silicide layer on a portion of a top surface of the second active region that is spaced apart from the first silicide layer, a first contact on a top surface of the first silicide layer, and a second contact on a top surface of the second silicide layer. The electrical fuse is configured so that when a first reverse voltage that is higher than a threshold voltage is applied to the electrical fuse through the first and second contacts, the P/N junction is broken down by a reverse current flowing between the first and second active regions so that the electrical fuse is rendered conductive in response to a second reverse voltage that is less than the threshold voltage.

The first and second active regions may be on a top surface of a semiconductor substrate.

The electrical fuse may further include a well region on the top surface of the semiconductor substrate. The first and second active regions may be on the well region.

An impurity doping concentration of the second active region may be lower than an impurity doping concentration of the first active region and higher than an impurity doping concentration of the well region.

The first active region may be doped with P+ type impurities, the second active region may be doped with N− type impurities, and the well region may be a P-type well or an N-type well.

The electrical fuse may further include a shallow trench isolation (STI) region disposed at sides of the first and second active regions.

The electrical fuse may further include a P-well region and an N-well region which are on a semiconductor substrate. In such embodiments, the second active region may be on the N-well region and the first active region is on the P-well region.

An impurity doping concentration of the second active region may be lower than an impurity doping concentration of the first active region and higher than an impurity doping concentration of the N-well region and an impurity doping concentration of the P-well region.

The electrical fuse may include a fuse link portion in which the first active region contacts the second active region. The first active region may include a protrusion which protrudes into the second active region and the second active region may include a complimentary receiver which embraces the protrusion of the first active region.

A silicide layer may not be disposed on a top surface of the fuse link portion.

According to other embodiments of the present invention, there is provided a semiconductor integrated circuit including the above-described electrical fuse and a voltage application circuit that is configured to apply a reverse voltage that is higher than a threshold voltage to the electrical fuse through the first and second contacts so that a reverse current flows between the first and second active regions, thereby breaking down the P/N junction.

Pursuant to further embodiments of the present invention, semiconductor fuses are provided which include a semiconductor substrate, a well region on a top surface of the semiconductor substrate, a first semiconductor region having a first conductivity type on a top surface of the semiconductor substrate, and a second semiconductor region having a second conductivity type that is opposite the first conductivity type on the top surface of the semiconductor substrate. In these fuses, the second semiconductor region contacts the first semiconductor region to form a horizontal P/N junction. A first silicide region is provided on the first semiconductor region and a second silicide region is provided on the second semiconductor region. A first contact is provided on the first silicide region and a second contact is provided on the second silicide region. An impurity doping concentration of the second semiconductor region is less than an impurity doping concentration of the first semiconductor region but greater than an impurity concentration of the well region. At least one of the first semiconductor region and the second semiconductor region is on the well region opposite the semiconductor substrate.

### BRIEF DESCRIPTION OF THE DRAWINGS

The above and other features and advantages of the present invention will become more apparent by describing in detail exemplary embodiments thereof with reference to the attached drawings in which:

FIG. 1 is a top view of an electrical fuse according to some embodiments of the present invention;

FIG. 2 is a schematic sectional view of the electrical fuse illustrated in FIG. 1;

FIG. 3 is a schematic sectional view of a modification of the electrical fuse illustrated in FIG. 2;

FIG. 4 is a top view of an electrical fuse according to additional embodiments of the present invention;

FIG. 5 is a top view of an electrical fuse according to still further embodiments of the present invention;

FIG. 6 is a schematic sectional view of the electrical fuse illustrated in FIG. 5;

FIG. 7 is a schematic sectional view of a modification of the electrical fuse illustrated in FIG. 6;

FIG. 8 is a flowchart of a method of fabricating an electrical fuse according to some embodiments of the present invention;

FIGS. 9A through 9F are sectional views of the stages in the method illustrated in FIG. 8; and

FIG. 10 is a schematic circuit diagram of a semiconductor integrated circuit including an electrical fuse according to some embodiments of the present invention.

### DETAILED DESCRIPTION OF THE EMBODIMENTS

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first region could be termed a second region, and, similarly, a second region could be termed a first region without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

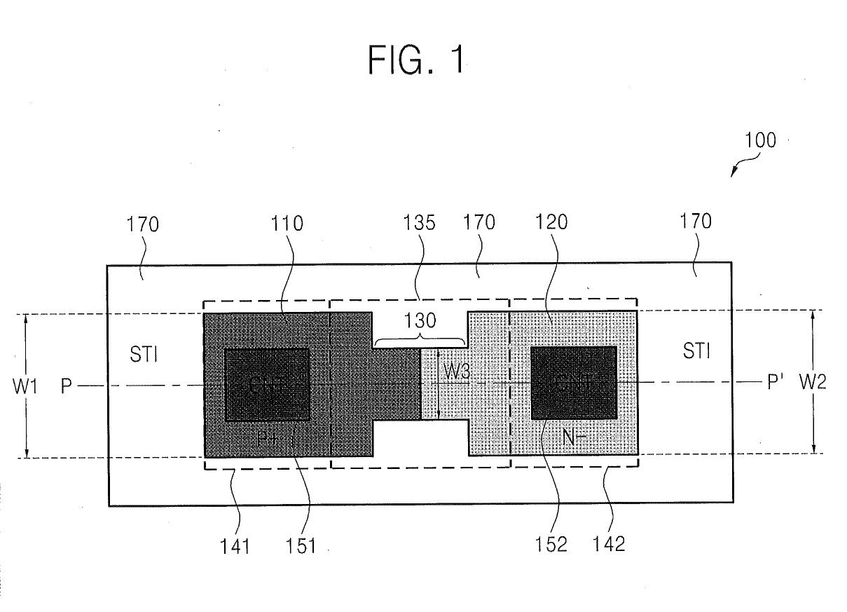

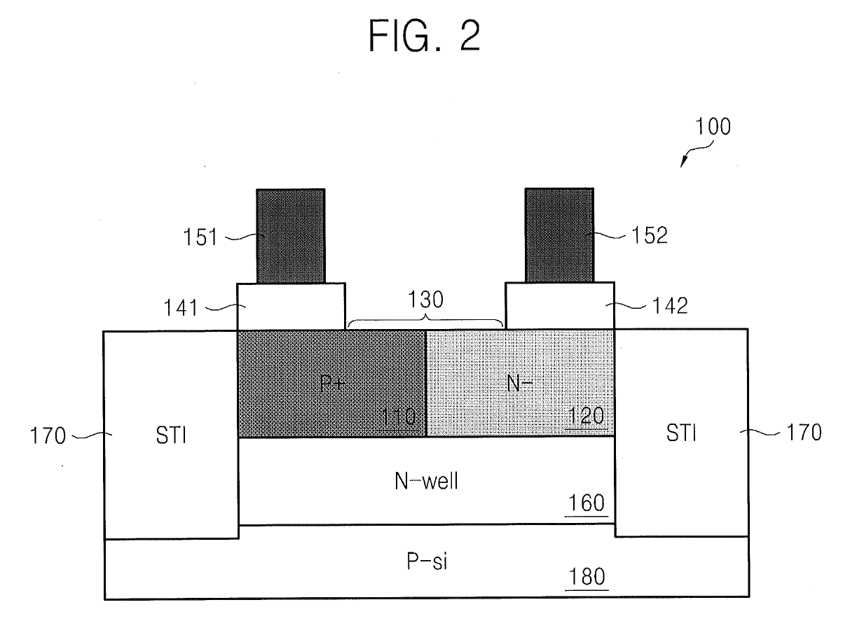

FIG. 1 is a top view of an electrical fuse 100 according to some embodiments of the present invention. FIG. 2 is a schematic sectional view of the electrical fuse 100 illustrated in FIG. 1, taken along the line P-P′.

Referring to FIGS. 1 and 2, a well 160 is disposed on a semiconductor substrate 180 in the electrical fuse 100. The semiconductor substrate 180 may be a bulk semiconductor substrate, a semiconductor-on-insulator substrate, a semiconductor epitaxial layer or the like. A first active region 110 for a first electrode and a second active region 120 for a second electrode are disposed on top of the well 160. An isolation region 170 for isolating the electrical fuse 100 from other circuits is disposed in the region of the electrical fuse 100 other than the active regions 110 and 120. In some embodiments, the isolation region 170 may surround the active regions 110 and 120. The isolation region 170 may comprise a field oxide region and may be implemented using shallow trench isolation (STI), but the present invention is not restricted thereto.

A first silicide layer 141 may be disposed on top of the first active region 110 and a second silicide layer 142 may be disposed on top of the second active region 120. A first contact 151 may be disposed on top of the first silicide layer 141 and a second contact 152 may be disposed on top of the second silicide layer 142. For instance, the first silicide layer 141 may be disposed on a portion of a top surface of the first active region 110 and the second silicide layer 142 may be disposed on a portion of a top surface of the second active region 120. The second silicide layer 142 is separate and spaced-apart from the first silicide layer 141 (i.e., a region which does not include a silicide layer is disposed between the first and second silicide layers 141 and 142). The portions of the first and second active regions 110 and 120 that join to each other do not have a silicide layer thereon. The portions of the top surfaces of the first and second active regions 110 and 120 which do not have a silicide layer thereon are collectively referred to herein as a silicide block layer (SBL) 135.

The portions of the first and second active regions 110 and 120 that join to each other are collectively referred to as a fuse link portion 130. A width W3 of the fuse link portion 130 may be less than a width W1 of the first active region 110 and less than a width W2 of the second active region 120. Although it is illustrated in FIG. 1 that the width W1 of the first active region 110 is similar to or the same as the width W2 of the second active region 120, the widths W1 and W2 may be different from each other. The width W3 of the fuse link portion 130 may be the same as the width W1 of the first active region 110 and/or the width W2 of the second active region 120.

In some embodiments, the first and second silicide layers 141 and 142 may be made from titanium silicide, cobalt silicide, nickel silicide, or a combination or an alloy thereof.

The well 160 may be an N-well or a P-well. The well 160 may have a conductivity type that is opposite the conductivity type of the underlying substrate.

The first active region 110 may be formed by doping a polysilicon region with P+ type impurities and the second active region 120 may be formed by doping a polysilicon region with N− type impurities. The impurity (e.g., P+ type impurity) doping concentration of the first active region 110 may be, for example, approximately 1×10¹³ to 1×10¹⁵ atoms/cm². The impurity (e.g., N− type impurity) doping concentration of the second active region 120 may be lower than P+ type impurity doping concentration of the first active region 110 and may be, for example, approximately 1×10¹² to 1×10¹⁴ atoms/cm². When the well 160 is doped with N type impurities, an N-well may be formed. When the well 160 is doped with P type impurities, a P-well may be formed. The doping concentration of the well 160 may be lower than the doping concentration of the second active region 120. For example, the doping concentration of the well 160 may be approximately 1×10¹¹ to 1×10¹² atoms/cm².

As shown in FIG. 1, the fuse link portion 130 at which an end of the first active region 110 joins to an end of the second active region 120 is positioned between the first active region 110 and the second active region 120. One side of the fuse link portion 130 may be doped with the same impurities as the first active region 110 and the other side of the fuse link portion 130 may be doped with the same impurities as the second active region 120. In other words, polysilicon that is part of the first active region 110 in the fuse link portion 130 is doped with P+ type impurities and polysilicon that is part of the second active region 120 in the fuse link portion 130 is doped with N− type impurities.

Accordingly, the fuse link portion 130 forms a P+/N− junction. Such a P+/N− junction where a P+ region and an N− region directly join to each other is referred to as a butting junction. Therefore, in some embodiments of the present invention, a fuse is provided that is a butting junction fuse (BJF). As described above, a silicide layer is not disposed on the top of the fuse link portion 130. The following description will focus on an electrical fuse using the P+/N− junction, but the present invention is not restricted thereto. For instance, an N+/P− junction, a N−/P+ junction or a P−/N+ junction may be used instead of the P+/N− junction. In other words, the first and second active regions 110 and 120 may be respectively implemented (1) as an N+ doped region and a P− doped region, (2) as an N− doped region and a P+ doped region, or (3) as a P− doped region and an N+ doped region instead of as a P+ doped region and an N− doped region.

When a reverse voltage higher than a threshold voltage is applied to the electrical fuse 100 through the first and second contacts 151 and 152, a reverse current flows between the first and second active regions 110 and 120. A voltage application circuit (not shown) for applying a voltage to the electrical fuse 100 may be provided. For instance, a semiconductor device (e.g., a memory device) may include the electrical fuse 100 and a voltage application circuit which applies a predetermined voltage to the electrical fuse 100.

When a reverse voltage higher than a threshold voltage is applied by the voltage application circuit to the electrical fuse 100 through the first and second contacts 151 and 152, a reverse current higher than a predetermined value flows between the first and second active regions 110 and 120. As a result, a P/N junction (e.g., the P+/N− junction) is broken down, and therefore, the properties of the electrical fuse 100 change. For instance, in some embodiments, when a reverse voltage of at least +9.0 V is applied between the second contact 152 and the first contact 151, P/N junction breakdown occurs. As a result, a predetermined current flows in the electrical fuse 100 even when a reverse voltage that is lower than the threshold voltage is applied to the first and second contacts 151 and 152.

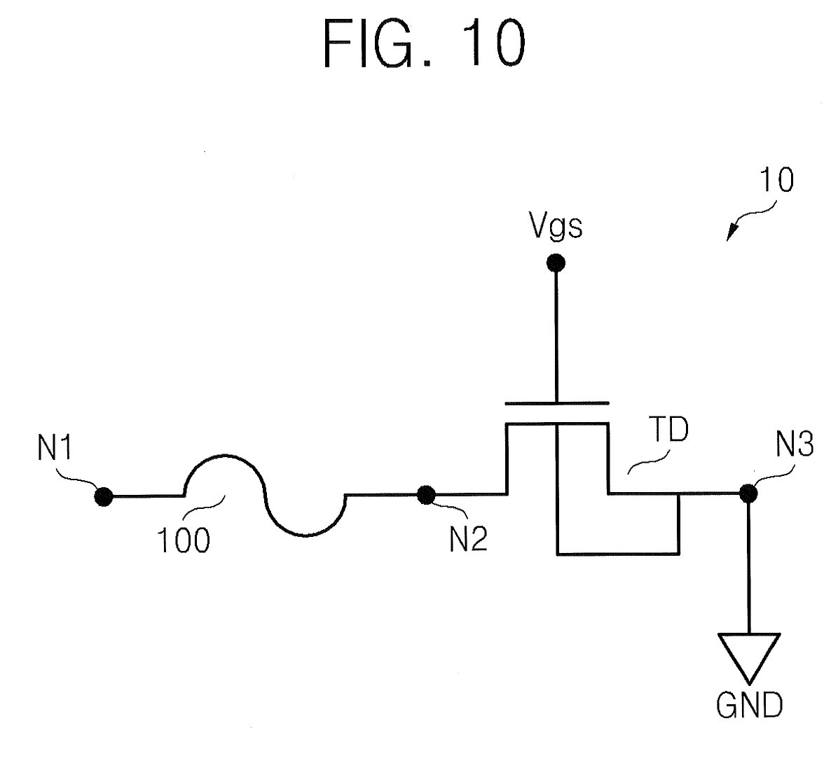

FIG. 10 is a schematic circuit diagram of a semiconductor integrated circuit 10 including the electrical fuse 100 according to some embodiments of the present invention. The semiconductor integrated circuit 10 includes the electrical fuse 100 and a voltage application circuit which applies a necessary voltage to the electrical fuse 100. The voltage application circuit includes a drive transistor TD.

As illustrated in FIG. 10, a terminal (e.g., the first contact 151) of the electrical fuse 100 may be connected to a first node N1 and another terminal (e.g., the second contact 152) of the electrical fuse 100 may be connected to a drain terminal N2 of the drive transistor TD. To program the electrical fuse 100, a reverse voltage of a predetermined magnitude (e.g., −9.0 V) is applied to the electrical fuse 100 through the first node N1 and a voltage Vgs that can turn on the drive transistor TD is applied to a gate of the drive transistor TD. P/N junction breakdown occurs in response to this voltage, and the electrical fuse 100 is thereby programmed. Whether the electrical fuse 100 has been programmed may be determined based on a difference between a current before the programming of the electrical fuse 100 and a current after the programming of the electrical fuse 100.

Since the doping concentration of the second active region 120 is higher than the doping concentration of the well 160 and the doping concentration of the first active region 110 is higher than the doping concentration of the second active region 120, the width of a depletion region between the first and second active regions 110 and 120, i.e., a depletion region of the P+/N− junction, is less than the width of a depletion region between the second active region 120 and the well 160. Accordingly, junction breakdown occurs between the first active region 110 and the second active region 120, that is, junction breakdown occurs at the P+/N− junction. A position of junction breakdown may be controlled using the above-described method.

As shown in FIGS. 1 and 2, according to some embodiments of the present invention, a horizontal P/N junction is formed in the electrical fuse 100. Herein the term “horizontal P/N junction” refers to a P/N junction is formed between a P-type region and an N-type region that are located at the same height (or at least overlapping heights) above a top surface of an underlying semiconductor substrate so that the junction defines one or more planes that intersect, typically at a right angle, the underlying semiconductor substrate. In contrast, a “vertical” P/N junction is a junction formed between a P-type region and an N-type region that are located at different heights above a top surface of an underlying semiconductor substrate, where the junction is typically parallel to the top surface of the underlying semiconductor substrate. Although the electrical fuse 100 having the horizontal P/N junction has a relatively larger area than an electrical fuse having a vertical P/N junction, it is more reliable in terms of isolation between electrical fuses, thereby reducing inter-talk between devices. The area of the electrical fuse 100 may be reduced by using a butting junction in which a P/N junction is directly made.

According to the current embodiments of the present invention, a silicide layer is not disposed on the top surface of the fuse link portion 130. In addition, resistance around the fuse link portion 130 may be increased by making the width W3 of the fuse link portion 130 less than the width W1 of the first active region 110 and/or the width W2 of the second active region 120, so that thermal heat is increased. Accordingly, a program current may be controlled when the electrical fuse 100 is programmed. In other words, the program current may be controlled by adjusting the width W3 of the fuse link portion 130.

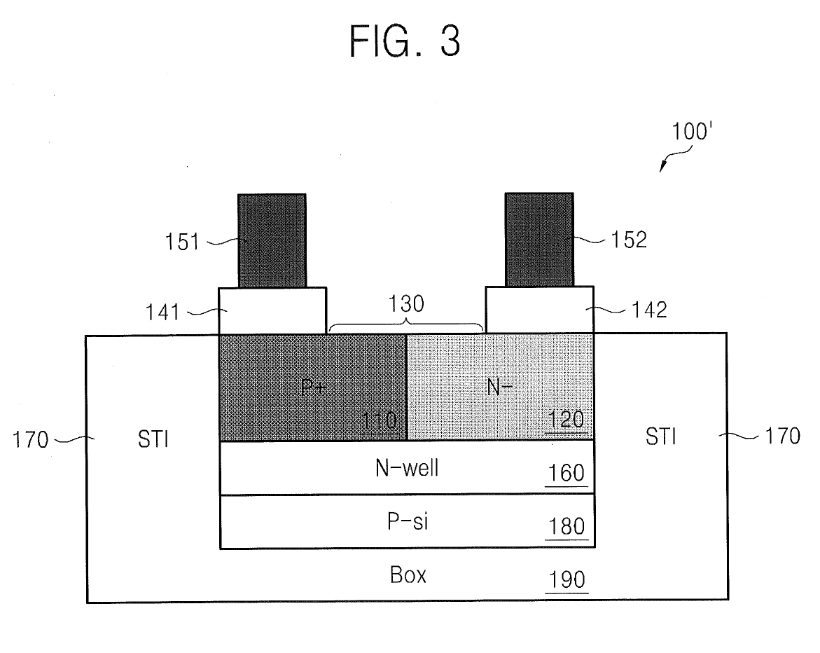

FIG. 3 is a schematic sectional view of an electrical fuse 100′ that is a modified version of the electrical fuse 100 illustrated in FIG. 2, taken along the line P-P′ illustrated in FIG. 1.

The electrical fuse 100′ illustrated in FIG. 3 is similar to the electrical fuse 100 illustrated in FIG. 2. To avoid redundancy, the description below will focus on the different features of the electrical fuse 100′.

Referring to FIG. 3, the electrical fuse 100′ has a silicon-on-insulator (SOI) structure. In other words, the electrical fuse 100′ may be formed on an SOI wafer. The SOI wafer includes a buried oxide (BOX) layer 190 formed in a semiconductor substrate. The BOX layer 190 is a thin insulation layer (e.g., an oxide layer) that is disposed between substrates and blocks leakage current. In particular, in the modification illustrated in FIG. 3, the BOX layer 190 of the SOI wafer connects to the isolation region 170 (or an STI region 170) thereby completely isolating the electrical fuse 100′. As a result, the electrical fuse 100′ may have improved inter-talk performance.

The first and second active regions 110 and 120 are disposed on the well 160 in the above-described embodiments, but the present invention is not restricted to these embodiments. For example, the first and second active regions 110 and 120 may be disposed on the semiconductor substrate 180 instead of the well 160.

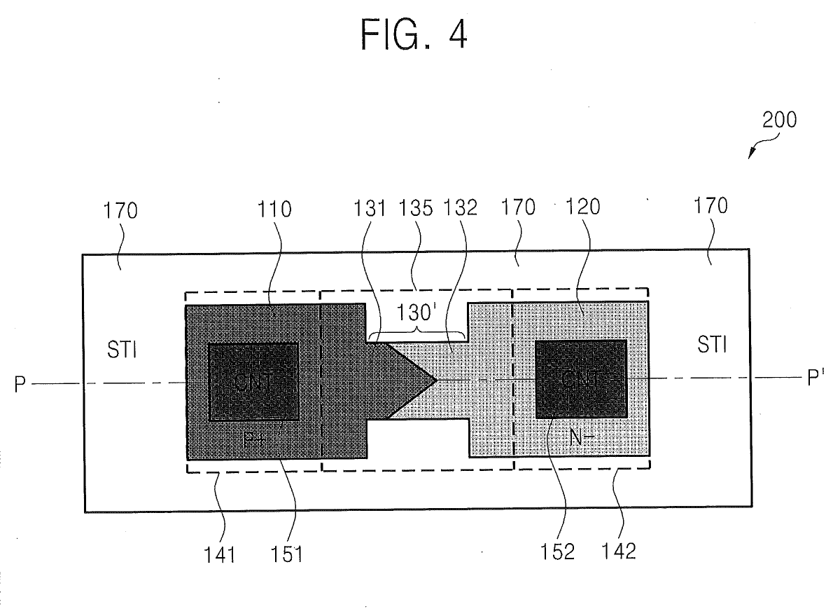

FIG. 4 is a top view of an electrical fuse 200 according to additional embodiments of the present invention. The electrical fuse 200 illustrated in FIG. 4 is similar to the electrical fuse 100 illustrated in FIGS. 1 and 2. To avoid redundancy, the description of the electrical fuse 200 will focus on the different features of the electrical fuse 200.

Referring to FIG. 4, one of the first and second active regions 110 and 120 protrudes toward the other one of the first and second active regions 110 and 120.

A fuse link portion 130′ where the first and second active regions 110 and 120 join to form a P/N junction that includes a protrusion 131 and a receiver 132. The protrusion 131 is a part of the first active region 110 which protrudes toward the second active region 120. The receiver 132 is a part of the second active region 120 which embraces and holds the protrusion 131 of the first active region 110. The cross-section of the protrusion 131 may be a triangle, as illustrated in FIG. 4, but the present invention is not restricted thereto.

In the embodiments illustrated in FIG. 4, a current flow is concentrated near the protrusion 131 at the application of a reverse voltage. Accordingly, junction breakdown may occur at a lower reverse voltage than in the embodiments illustrated in FIGS. 1 through 3.

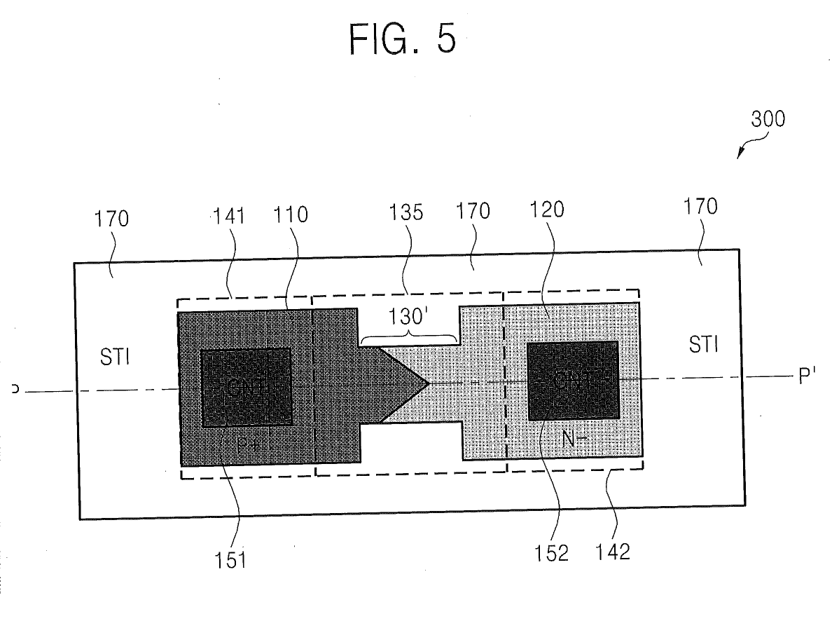

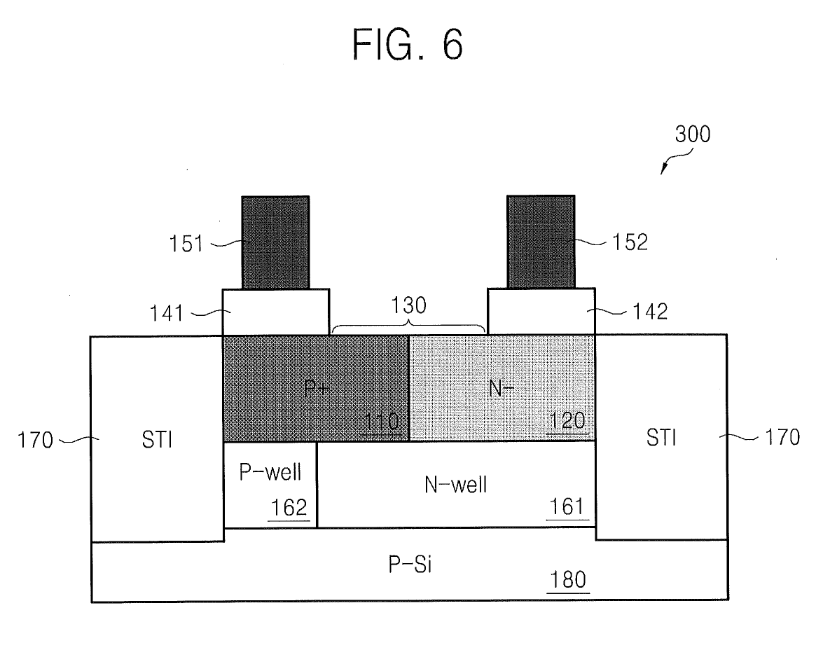

FIG. 5 is a top view of an electrical fuse 300 according to further embodiments of the present invention. FIG. 6 is a schematic sectional view of the electrical fuse 300 illustrated in FIG. 5, taken along the line P-P′.

The electrical fuse 300 illustrated in FIG. 5 is similar to the electrical fuse 200 illustrated in FIG. 4. To avoid redundancy, the description of the electrical fuse 300 will focus on the different features of the electrical fuse 300.

In the electrical fuse 300, an N-well 161 and a P-well 162 are disposed on the semiconductor substrate 180. The second active region 120 is disposed on the N-well 161 and the first active region 110 is disposed on the P-well 162 and on a part of the N-well 161. The location where the N-well 161 contacts the P-well 162 may be changed.

The N-well 161 may be formed using N-type impurity doping and the P-well 162 may be formed using P-type impurity doping. The impurity doping concentration of the N-well 161 may be similar to that of the P-well 162, but the present invention is not restricted thereto. The impurity doping concentration of the second active region 120 may be lower than the impurity doping concentration of the first active region 110 and higher than the impurity doping concentrations of the N-well 161 and the P-well 162.

When electrical over stress (EOS) such as static electricity is applied to a first electrode, i.e., the first contact 151 or the first active region 110, in the electrical fuse 300, a voltage applied to the first active region 110 may be discharged to the semiconductor substrate 180 through the P-well 162. Accordingly, the impact of electrostatic discharge (ESD) may be reduced. ESD may include static electricity and EOS.

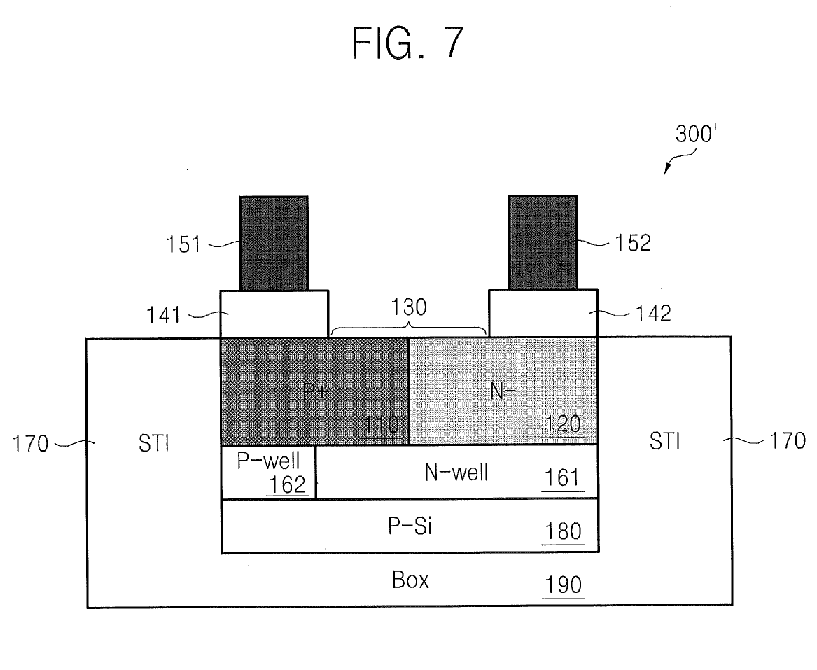

FIG. 7 is a schematic sectional view of a modification of the electrical fuse 300′ illustrated in FIG. 6, taken along the line P-P′ illustrated in FIG. 5. The electrical fuse 300′ illustrated in FIG. 7 is similar to the electrical fuse 100′ illustrated in FIG. 3. To avoid redundancy, the description of the electrical fuse 300′ will focus on the different features of the electrical fuse 300′.

Referring to FIG. 7, the electrical fuse 300′ may be formed on an SOI wafer like the electrical fuse 100′ illustrated in FIG. 3. In the embodiments illustrated in FIG. 7, the BOX layer 190 of the SOI wafer connects to the STI region 170, so that the electrical fuse 300′ can be completely isolated. Accordingly, the electrical fuse 300′ may have improved inter-talk performance.

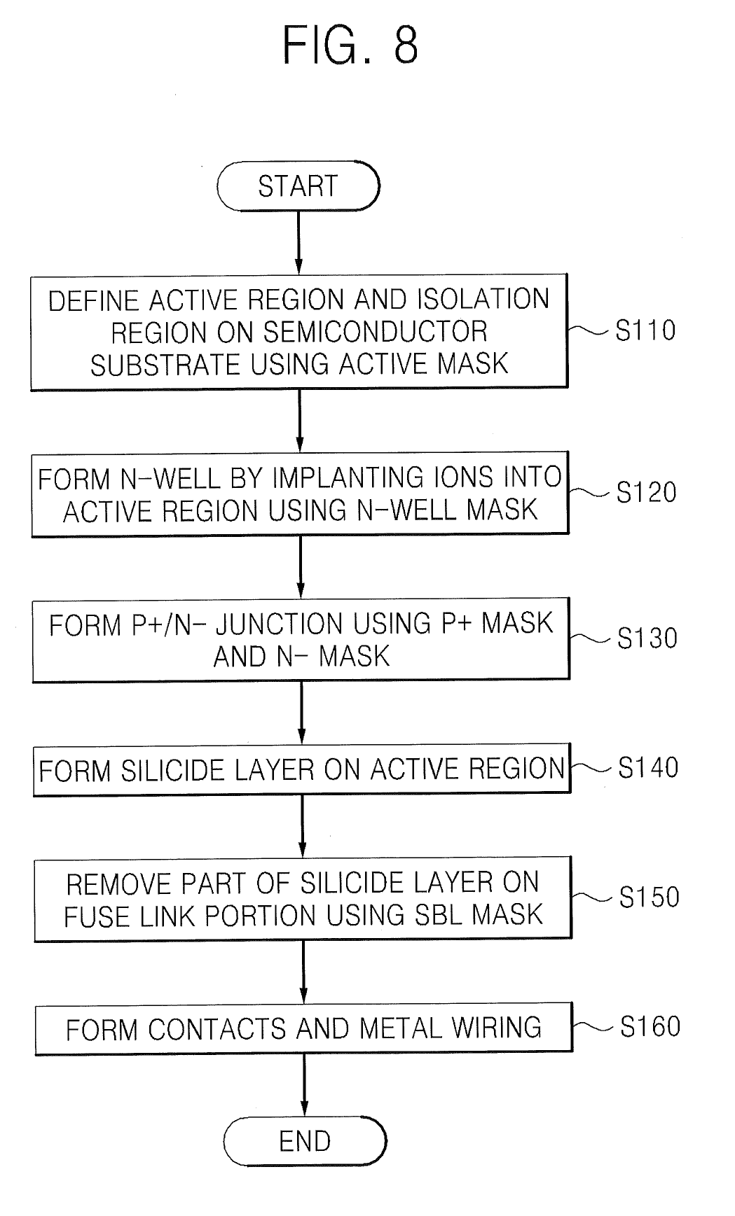

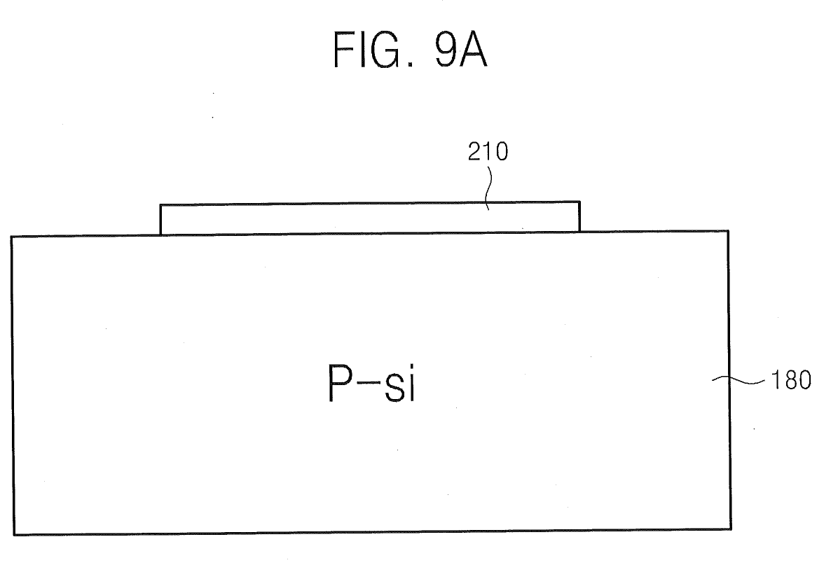

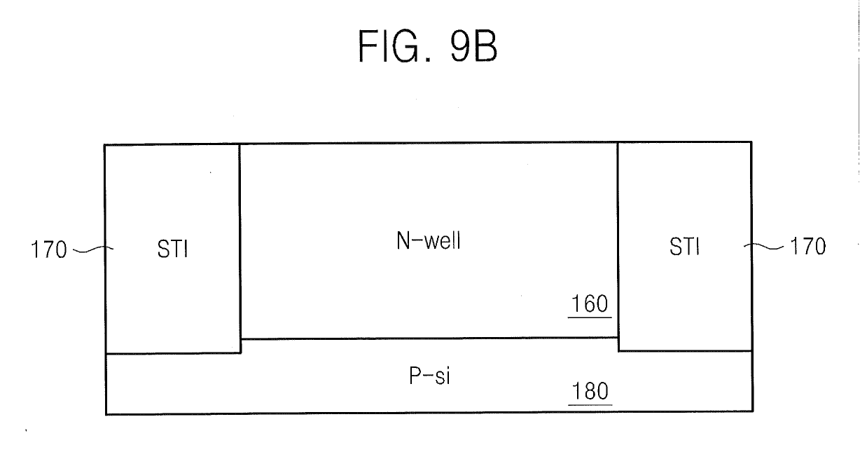

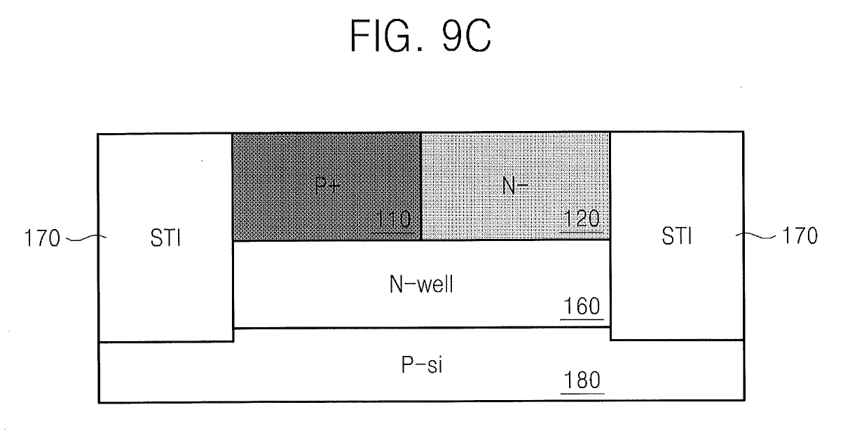

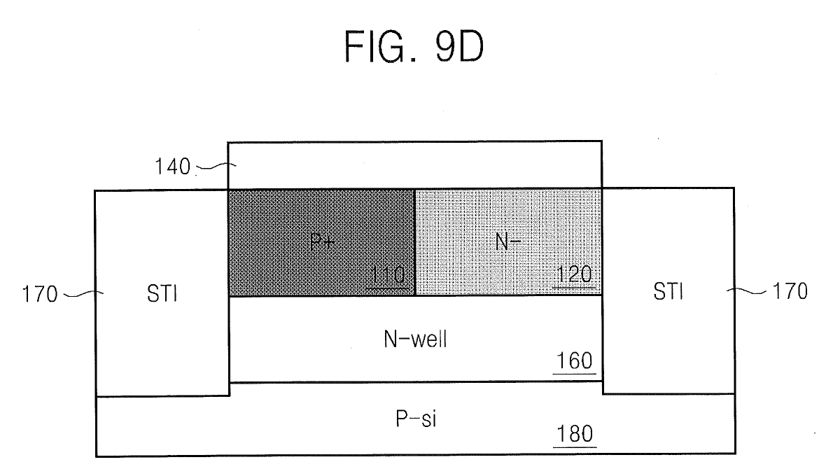

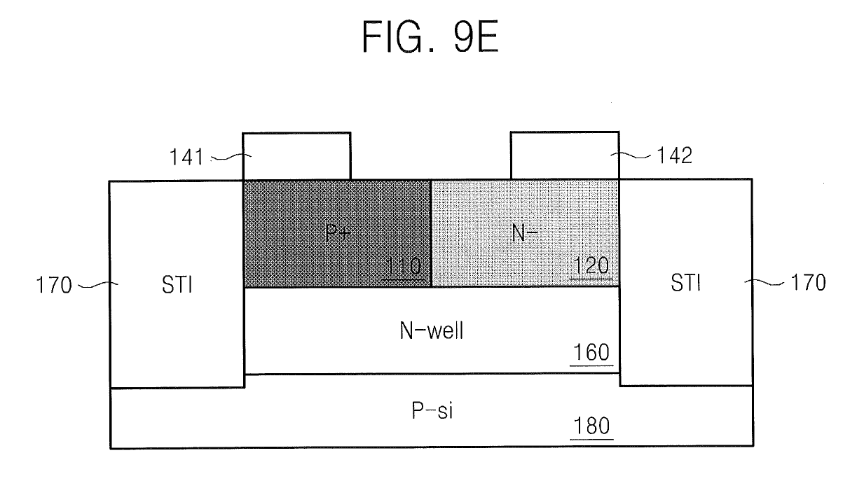

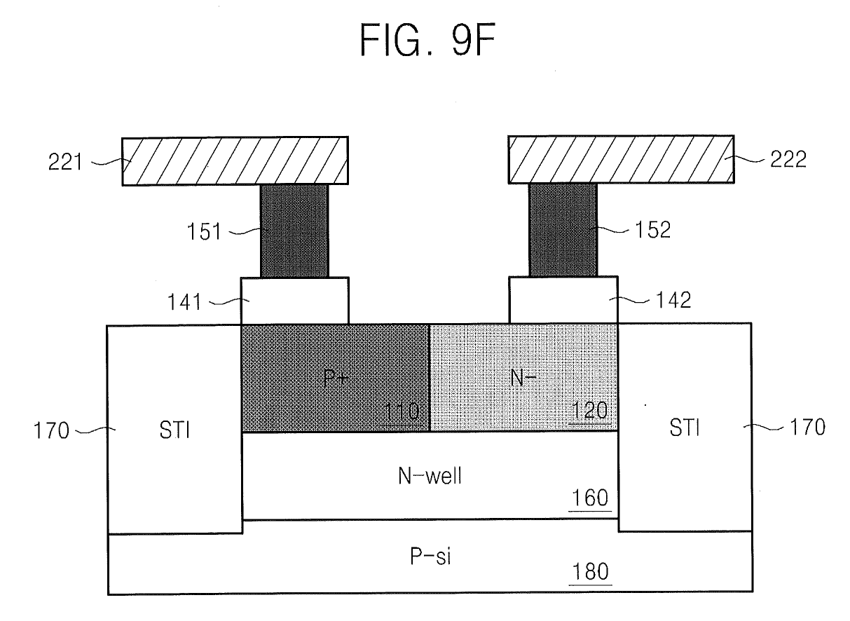

FIG. 8 is a flowchart of a method of fabricating an electrical fuse according to some embodiments of the present invention. FIGS. 9A through 9F are sectional views of the stages in the method illustrated in FIG. 8.

Referring to FIGS. 8 and 9A, an active region and the STI region 170 are defined on the semiconductor substrate 180 using an active mask 210 in operation S110. Referring to FIGS. 8 and 9B, the N-well 160 is formed by implanting ions into the active region using an N-well mask (not shown) in operation S120. Referring to FIGS. 8 and 9C, the P+ active region 110 is formed using a P+ mask (not shown) and then the N− active region 120 is formed using an N− mask (not shown) to form a P+/N− junction in operation S130. Referring to FIGS. 8 and 9D, a silicide layer 140 is formed on the active regions 110 and 120 in operation S140. Referring to FIGS. 8 and 9E, a portion of the silicide layer 140 that is formed on the top surface of the fuse link portion 130 is removed using an SBL mask (not shown) so that the silicide layers 141 and 142 are respectively formed at the both sides of the fuse link portion 130 in operation S150. Referring to FIGS. 8 and 9F, in operation S160 the contacts 151 and 152 are formed on the silicide layers 141 and 142, respectively, and then metal wiring 221 and 222 is formed that connects to the contacts 151 and 152, respectively.

As described above, according to some embodiments of the present invention, an electrical fuse uses P/N junction breakdown and has a structure connected to a bulk, i.e., a semiconductor substrate. Accordingly, even when stress like ESD is applied to the electrical fuse, a current path through which a high voltage is discharged can be formed from the electrical fuse to the bulk. As a result, the electrical fuse is less affected by electrical stress than conventional electrical fuses having an isolated structure in which it is difficult to form a current path through which the electrical stress is discharged. In addition, according to the embodiments of the present invention, since the electrical fuse uses a junction structure that may be less influenced by processes, it maintains a certain structure even if the processes are changed. Consequently, the electrical fuse may have higher compatibility with the processes.

While the present invention has been particularly shown and described with reference to exemplary embodiments thereof, it will be understood by those of ordinary skill in the art that various changes in forms and details may be made therein without departing from the spirit and scope of the present invention as defined by the following claims.

1. An electrical fuse comprising:
a first active region doped with first-type impurities;
a second active region doped with second-type impurities which forms a horizontal P/N junction with the first active region;
a first silicide layer on a portion of a top surface of the first active region;
a second silicide layer on a portion of a top surface of the second active region that is spaced apart from the first silicide layer;
a first contact on a top surface of the first silicide layer; and
a second contact on a top surface of the second silicide layer,
wherein the electrical fuse is configured so that when a first reverse voltage that is higher than a threshold voltage is applied to the electrical fuse through the first and second contacts, the P/N junction is broken down by a reverse current flowing between the first and second active regions so that the electrical fuse is rendered conductive in response to a second reverse voltage that is less than the threshold voltage.

2. The electrical fuse of claim 1, wherein the first and second active regions are on a top surface of a semiconductor substrate.

3. The electrical fuse of claim 2, further comprising a well region on the top surface of the semiconductor substrate, wherein the first and second active regions are on the well region.

4. The electrical fuse of claim 3, wherein an impurity doping concentration of the second active region is lower than an impurity doping concentration of the first active region and higher than an impurity doping concentration of the well region.

5. The electrical fuse of claim 4, wherein the first active region is doped with P+ type impurities, the second active region is doped with N− type impurities, and the well region is a P-type well or an N-type well.

6. The electrical fuse of claim 1, further comprising a shallow trench isolation (STI) region disposed at sides of the first and second active regions.

7. The electrical fuse of claim 1, further comprising a P-well region and an N-well region which are on a semiconductor substrate,
wherein the second active region is on the N-well region and the first active region is on the P-well region.

8. The electrical fuse of claim 7, wherein an impurity doping concentration of the second active region is lower than an impurity doping concentration of the first active region and higher than an impurity doping concentration of the N-well region and an impurity doping concentration of the P-well region.

9. The electrical fuse of claim 1, wherein the electrical fuse includes a fuse link portion in which the first active region contacts the second active region, and wherein the first active region includes a protrusion which protrudes into the second active region and the second active region includes a complimentary receiver which embraces the protrusion of the first active region.

10. The electrical fuse of claim 9, wherein a silicide layer is not disposed on a top surface of the fuse link portion.

11. A semiconductor integrated circuit comprising:
an electrical fuse comprising a first active region doped with first-type impurities, a second active region doped with second-type impurities that forms a horizontal P/N junction with the first active region, a first silicide layer on a portion of a top surface of the first active region, a second silicide layer on a portion of a top surface of the second active region that is spaced apart from the first silicide layer, a first contact on a top surface of the first silicide layer and a second contact on a top surface of the second silicide layer; and
a voltage application circuit that is configured to apply a reverse voltage that is higher than a threshold voltage to the electrical fuse through the first and second contacts so that a reverse current flows between the first and second active regions, thereby breaking down the P/N junction.

12. The semiconductor integrated circuit of claim 11, wherein the electrical fuse further comprises a well region on a top surface of a semiconductor substrate, wherein the first and second active regions are on the well region opposite the semiconductor substrate.

13. The semiconductor integrated circuit of claim 12, wherein an impurity doping concentration of the second active region is lower than an impurity doping concentration of the first active region and higher than an impurity doping concentration of the well region.

14. A semiconductor fuse, comprising:
a semiconductor substrate;
a well region on a top surface of the semiconductor substrate;
a first semiconductor region having a first conductivity type on a top surface of the semiconductor substrate;
a second semiconductor region having a second conductivity type that is opposite the first conductivity type on the top surface of the semiconductor substrate, the second semiconductor region contacting the first semiconductor region to form a horizontal P/N junction;
a first silicide region on the first semiconductor region;
a second silicide region on the second semiconductor region;
a first contact on the first silicide region; and
a second contact on the second silicide region,
wherein an impurity doping concentration of the second semiconductor region is less than an impurity doping concentration of the first semiconductor region but greater than an impurity concentration of the well region, and
wherein at least one of the first semiconductor region and the second semiconductor region is on the well region opposite the semiconductor substrate.

15. The semiconductor fuse of claim 14, wherein the well region comprises a first well region, further comprising a second well region on the top surface of the semiconductor substrate that is adjacent the first well region and underneath at least one of the first and second semiconductor regions, and wherein the impurity doping concentration of the second semiconductor region exceeds an impurity doping concentration of the second well region.

16. The semiconductor fuse of claim 14, further comprising an isolation region that isolates the semiconductor fuse from an adjacent semiconductor fuse.

17. The semiconductor fuse of claim 14, wherein a first portion of the first semiconductor region that is under the first silicide region has a first width and a second portion of the first semiconductor region that is adjacent the P/N junction has a second width that is less than the first width, and wherein a first portion of the second semiconductor region that is under the second silicide region has a third width and a second portion of the second semiconductor region that is adjacent the P/N junction has a fourth width that is less than the third width.

18. The semiconductor fuse of claim 17, wherein one of the second portion of the first semiconductor region and the second portion of the second semiconductor region includes a protrusion and the other of the second portion of the first semiconductor region and the second portion of the second semiconductor region includes a receiver.

19. The semiconductor fuse of claim 14, in combination with a voltage application circuit that is configured to apply a reverse voltage to the semiconductor fuse through the first and second contacts that is sufficient to break down the P/N junction.

20. The semiconductor fuse of claim 19, wherein the voltage application circuit comprises a transistor that has a drain terminal that is connected to one of the first or second contacts.

21. (canceled)
